(19) United States
(12) Patent Application Publication
(10) Pub. No.: US 2026/0074007 A1
(43) Pub. Date: Mar. 12, 2026

(54) SEMICONDUCTOR MEMORY DEVICE AND OPERATING METHOD THEREOF

(71) Applicant: SAMSUNG ELECTRONICS CO., LTD., Suwon-si (KR)

(72) Inventors: Myung Kyu Lee, Suwon-si (KR); Ki Jun Lee, Suwon-si (KR); Kyo Min Sohn, Suwon-si (KR); Hyun-Chul Yoon, Suwon-si (KR); Chang Young Lee, Suwon-si (KR)

(21) Appl. No.: 19/242,750

(22) Filed: Jun. 18, 2025

(30) Foreign Application Priority Data
Sep. 12, 2024 (KR) 10-2024-0124410

(51) Int. Cl. G11C 29/52; G11C 5/14; G11C 11/408

(52) U.S. Cl. CPC G11C 29/52; G11C 5/144; G11C 11/4087

(57) ABSTRACT

A memory device is provided. A memory device comprises a decoder configured to receive first input data that is based on host data and a first data bus inversion (DBI) signal indicating whether the first input data is inverted, and output the host data, a counter configured to count a number of bits with a first value in the first DBI signal, an indicator generation circuit configured to generate an indicator signal based on a first counting value indicative of the number of bits with the first value in the first DBI signal, and a data selection circuit configured to receive the host data and, in response to the indicator signal, select write data to be stored in a memory cell array.

### CROSS-REFERENCE TO RELATED APPLICATION

This application claims priority under 35 U.S.C. § 119 to Korean Patent Application No. 10-2024-0124410 filed on Sep. 12, 2024, in the Korean Intellectual Property Office, and all the benefits accruing therefrom, the contents of which in its entirety are herein incorporated by reference.

### BACKGROUND

A memory system includes a memory controller and a memory device, and the memory controller and the memory device can transmit and receive data through a plurality of data signal lines. To reduce power consumption during data transmission and reception, a data encoding method such as data bus inversion (hereinafter, “DBI”) may be utilized. A transmitting device and a receiving device can support a DBI interface using DBI signals. Accordingly, the transmitting device can generate transmission data by selectively inverting at least some bits of the transmission data using a DBI encoding method and transmit a DBI signal indicating that at least some bits of the transmission data have been inverted, along with the transmission data, thereby reducing overall power consumption for data transmission.

However, when data is stored in memory cells, there is a need for a technology to ensure that the number of data 1s per page is maintained below a predetermined level to reduce power consumption.

### SUMMARY

Aspects of the present disclosure provide a semiconductor memory device with reduced power consumption.

Aspects of the present disclosure also provide a semiconductor memory device with enhanced system stability.

Aspects of the present disclosure also provide an operating method of a semiconductor memory device with reduced power consumption.

Aspects of the present disclosure also provide an operating method of a semiconductor memory device with enhanced system stability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided A memory device comprising a decoder configured to receive first input data generated by host data and a first data bus inversion (DBI) signal determining whether the first input data is inverted, and output the host data, a counter configured to count a number of bits with a first value in the first DBI signal, an indicator generation circuit configured to generate an indicator signal based on a first counting value obtained by counting the number of bits with the first value and a data selection circuit configured to receive the host data and, in response to the indicator signal, select write data to be stored in a memory cell.

According to the aforementioned and other embodiments of the present disclosure, an operating method of a memory device, comprising generating, by a decoder, host data based on first input data and a first data bus inversion (DBI) signal determining whether the first input data is inverted, generating, by a counter, a first counting value based on a number of bits with a first value in the first DBI signal, generating, by an indicator generation circuit, an indicator signal composed of one bit based on the first counting value, generating, by an inverter, inverted host data by inverting all bits of the host data, and selecting and outputting, by a data selection circuit, one of the host data and the inverted host data as write data based on the indicator signal.

According to the aforementioned and other embodiments of the present disclosure, a memory device includes a decoder configured to receive first input data generated by host data and a first data bus inversion (DBI) signal indicating whether the first input data is inverted, and output the host data; an inverter configured to generate inverted host data by inverting all bits of the host data; a counter configured to count a number of bits with a first value in the first DBI signal; an indicator generation circuit configured to generate an indicator signal based on a first counting value indicative of the number of bits with the first value in the first DBI signal; an error correction code (ECC) circuit configured to receive the host data and a default indicator signal and output parity bits; a data selection circuit configured to receive the host data and the inverted host data, in response to the indicator signal, select the host data or the inverted host data as write data; and a memory cell array configured to store (i) the write data; (ii) the indicator signal; and (iii) the parity bits or updated parity bits.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating an example of a memory system according to some embodiments.

FIG. 2 is a block diagram of the memory device of FIG. 1.

FIG. 3 is a block diagram illustrating some components included in the memory device of FIG. 2.

FIG. 4 is a table for explaining input data and the DBI signal.

FIG. 5 is a block diagram illustrating an example of a data transformation circuit according to some embodiments.

FIG. 6 is a diagram illustrating the data transformation circuit according to some embodiments.

FIGS. 7 through 11 are tables provided to explain the operation and effects of the data transformation circuit of FIG. 3.

FIG. 12 is a flowchart illustrating an example of an operation of the data transformation circuit of FIG. 5.

FIGS. 13 and 14 are block diagrams illustrating examples of data transformation circuits according to some embodiments.

FIG. 15 is a block diagram illustrating an example of a memory system according to some embodiments.

### DETAILED DESCRIPTION

Implementations of the present disclosure will hereinafter be described in detail with reference to the accompanying drawings. Identical reference numerals are used for identical components in the drawings, and redundant descriptions thereof will be omitted.

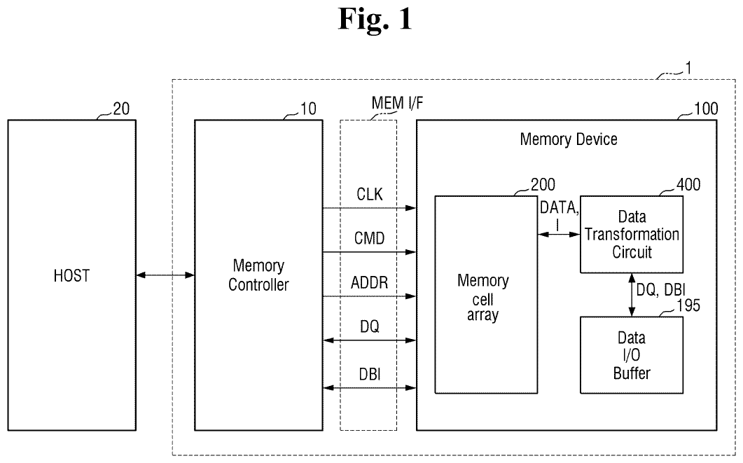

FIG. 1 is a block diagram illustrating a memory system according to some embodiments.

Referring to FIG. 1, a memory system 1 may include a host device 20 and a memory storage device 1. The memory storage device 1 may include a memory device 100 and a memory controller 10.

The memory controller 10 may generally control the operation of the memory device 100. For example, the memory controller 10 may control the exchange of data between an external host device 20 and the memory device 100. Specifically, the memory controller 10 may control the memory device 100 upon request from the host device 20, enabling data to be written to or read from the memory device 100.

The memory controller 10 and the memory device 100 may communicate via a memory interface MEM I/F. Additionally, the memory controller 10 and the external host device 20 may communicate via a host interface. In other words, the memory controller 10 may mediate signals between the memory device 100 and the host device 20. The memory controller 10 may apply a command CMD to control the operation of the memory device 100. Here, the memory device 100 may include dynamic memory cells. For example, the memory device 100 may include, but is not limited to, dynamic random access memory (DRAM), double data rate 4 synchronous DRAM (DDR4 SDRAM), low-power DDR4 SDRAM (LPDDR4 SDRAM), or LPDDR5 SDRAM, but is not limited thereto. Alternatively, the memory device 100 may include a non-volatile memory device. However, in this embodiment, the memory device 100 will hereinafter be described as being a volatile memory device.

The memory controller 10 may transmit a clock signal CLK, the command CMD, and an address ADDR to the memory device 100. The memory controller 10 may also provide data DQ and a data bus inversion (DBI) signal DBI to the memory device 100 and receive data DQ and a DBI signal DBI from the memory device 100. The memory device 100 may include a data input/output (I/O) buffer 195, a data transformation circuit 400 that converts input data DQ into write data DATA, and a memory cell array 200 where the write data DATA is stored.

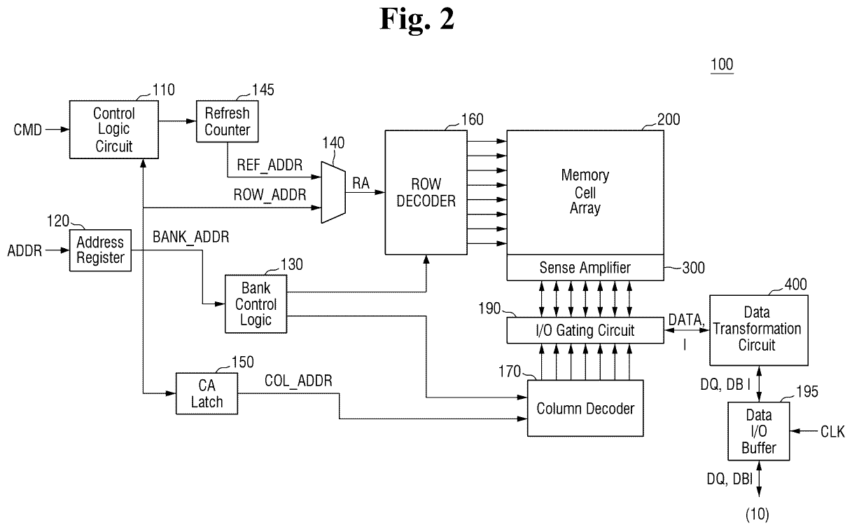

FIG. 2 is a block diagram of the memory device of FIG. 1.

Referring to FIG. 2, the memory device 100 may include a control logic circuit 110, an address register 120, a bank control logic circuit 130, a row address multiplexer 140, a refresh counter 145, a column address latch 150, a row decoder 160, a column decoder 170, the memory cell array 200, a sense amplifier section 300, an I/O gating circuit 190, the data transformation circuit 400, and the data I/O buffer 195.

The memory cell array 200 may include a plurality of bank arrays. The row decoder 160 may be connected to the plurality of bank arrays. The column decoder 170 may also be connected to the plurality of bank arrays. The sense amplifier section 300 may be connected to each of the plurality of bank arrays. The memory cell array 200 may include a plurality of wordlines, a plurality of bitlines, and a plurality of memory cells formed at intersections between the wordlines and the bitlines.

The address register 120 may receive the address ADDR from the memory controller 10. The address ADDR may include a bank address BANK_ADDR, a row address ROW_ADDR, and a column address COL_ADDR. The address register 120 may provide the bank address BANK_ADDR to the bank control logic circuit 130. The address register 120 may provide the row address ROW_ADDR to the row address multiplexer 140. The address register 120 may provide the column address COL_ADDR to the column address latch 150.

The bank control logic circuit 130 may generate a bank control signal in response to the bank address BANK_ADDR. The bank row decoder 160 may be activated in response to the bank control signal. Additionally, the column decoder 170 may be activated in response to the bank control signals corresponding to the bank address BANK_ADDR.

The row address multiplexer 140 may receive the row address ROW_ADDR from the address register 120 and a refresh row address REF_ADDR from the refresh counter 145. The row address multiplexer 140 may select one of the row address ROW_ADDR or the refresh row address REF_ADDR and output the selected address as a row address RA. The row address RA may be provided to the row decoder 160.

The refresh counter 145 may sequentially output the refresh row address REF_ADDR under the control of the control logic circuit 110.

The row decoder 160, activated by the bank control logic circuit 130, may decode the row address RA output from the row address multiplexer 140 and activate a wordline corresponding to the row address RA. For example, the row decoder 160 may apply a wordline driving voltage to the wordline corresponding to the row address RA.

The column address latch 150 may receive the column address COL_ADDR from the address register 120 and temporarily store the column address COL_ADDR. The column address latch 150 may incrementally increase the column address COL_ADDR received in burst mode. The column address latch 150 may provide the temporarily stored or incrementally increased column address COL_ADDR to the column decoder 170.

The column decoder 170, activated by the bank control logic circuit 130, may activate the sense amplifier section 300 corresponding to the bank address BANK_ADDR and the column address COL_ADDR through the I/O gating circuit 190.

The I/O gating circuit 190 may include a circuit that gates I/O data, an input data mask logic, read data latches that store data output from the memory cell array 200, and write drivers that write data into the memory cell array 200.

The input data DQ and the DBI signal DBI provided by the memory controller 10 may be delivered to the data transformation circuit 400 through the data I/O buffer 195. The data transformation circuit 400 may generate the write data DATA and an indicator signal I, and the write data DATA and the indicator signal I may be delivered to the I/O gating circuit 190. The write data DATA and the indicator signal I provided to the I/O gating circuit 190 may be stored in the memory cell array 200 via the sense amplifier section 300.

The memory cell array 200 may be connected to the sense amplifier section 300, and the row decoder 160 and the column decoder 170 may be connected to both the memory cell array 200 and the sense amplifier section 300. The bitlines included in the memory cell array 200 may be connected to the sense amplifier section 300 in an open bitline structure. This will be described later in further detail.

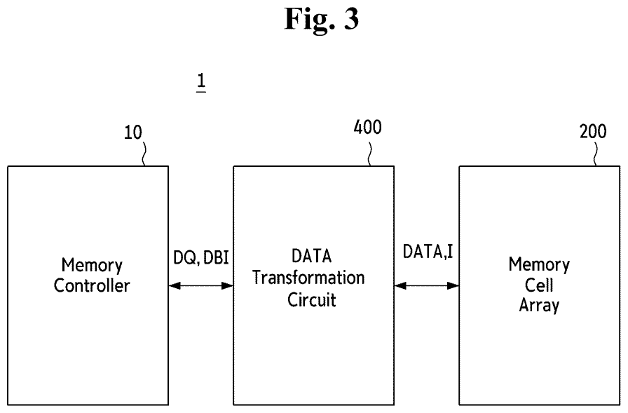

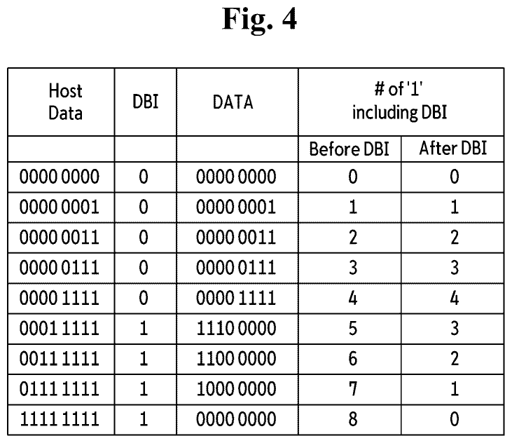

FIG. 3 is a block diagram illustrating some components included in the memory device of FIG. 2. FIG. 4 is a table for explaining input data and the DBI signal.

Referring to FIGS. 3 and 4, the memory system 1 may include the memory controller 10, the data transformation circuit 400, and the memory cell array 200. The input data DQ and the DBI signal DBI provided by the memory controller 10 may be delivered to the data transformation circuit 400. Specifically, the input data DQ and the DBI signal DBI may be provided to the data transformation circuit 400 through a plurality of pins. In addition, the data transformation circuit 400 may deliver the input data DQ and the DBI signal DBI to the memory controller 10.

In some embodiments, the input data DQ may be 128 bits, and each bit of the DBI signal DBI may be generated for every 8 bits of the input data DQ. In other words, the DBI signal DBI for 128-bit input data DQ may be a 16-bit signal. However, the present disclosure is not limited to this, and the bit lengths of the input data DQ and the DBI signal DBI may vary. For the convenience of explanation, FIG. 4 assumes that the input data DQ is 8 bits and the DBI signal DBI is 1 bit.

When the input data DQ is transmitted via input data signal lines, the direct current (DC) may be relatively large for an input data signal corresponding to 1, and may be relatively small for an input data signal corresponding to 0. Therefore, to reduce the DC current of the channel, it is advantageous if the number of 1s in the data signals transmitted via the input data signal lines is smaller than the number of 0s.

If the number of 1s in host data HD is not greater than the number of 0s in the host data HD, the DBI signal DBI may be generated as a disable level, i.e., 0. In this case, the bits included in the host data HD may remain unchanged, and the host data HD may be transmitted via the input data signal lines. For example, if the host data HD is 00000001, the DBI signal DBI may be generated as 0, and the DBI-encoded input data DQ remains the same as the host data HD. Then, the input data DQ of 00000001 and the DBI signal DBI may be transmitted. In this case, the total number of 1s in the input data DQ may be 1, and may remain the same before and after DBI encoding.

Conversely, if the number of 1s is greater than the number of 0s in the host data HD, the DBI signal DBI may be generated as an enable level, i.e., 1. At this time, the bits included in the host data HD may be transformed or inverted, and the host data HD may be converted into input data DQ, which is transmitted via the plurality of input data signal lines. For example, if the host data HD is 00011111, the DBI signal DBI may be generated as 1, and the DBI-encoded input data DQ may be generated as 11100000. Then, the transformed input data DQ of 11100000 and the DBI signal DBI may be transmitted. In this case, the total number of 1s in the transmitted data signals may be 3, which is fewer than the total number of 1s before DBI encoding, thereby reducing power consumption during data transmission.

The data transformation circuit 400, which receives the input data DQ and the DBI signal DBI from the memory controller 10, may provide the write data DATA and the indicator signal I to the memory cell array 200.

The data transformation circuit 400 may perform an operation to maintain the total number of 1s stored in the memory cell array 200 below a predetermined level before storing the input data DQ in the memory cell array 200. Specifically, the data transformation circuit 400 may output the write data DATA, which is either the input data DQ as is or the inverted form of the input data DQ, based on the input data DQ and the DBI signal DBI. Additionally, the data transformation circuit 400 may generate and output the indicator signal I, which indicates whether the input data DQ has been inverted. By maintaining the total number of 1s included in the write data DATA stored in the memory cell array 200 below a predetermined level, power consumption can be reduced, thereby ensuring the stability of the memory system 1. The process of generating the write data DATA and the indicator signal I within the data transformation circuit 400 will be described later in further detail.

The memory cell array 200 may store the write data DATA and the indicator signal I generated by the data transformation circuit 400.

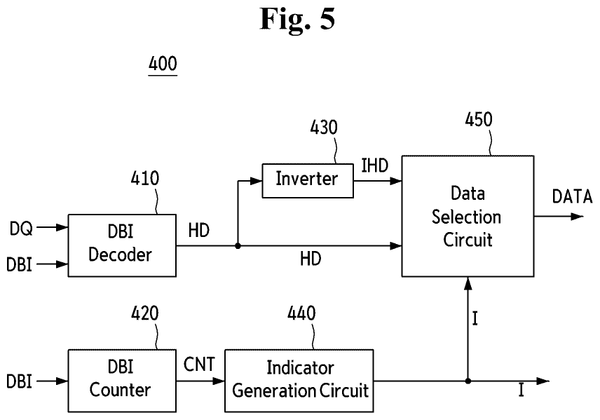

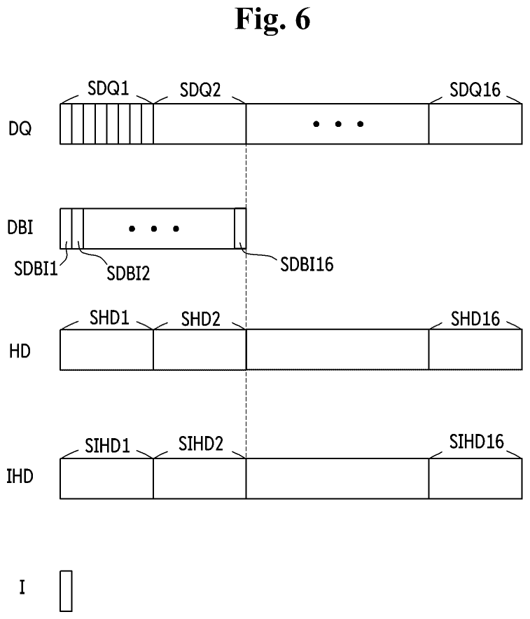

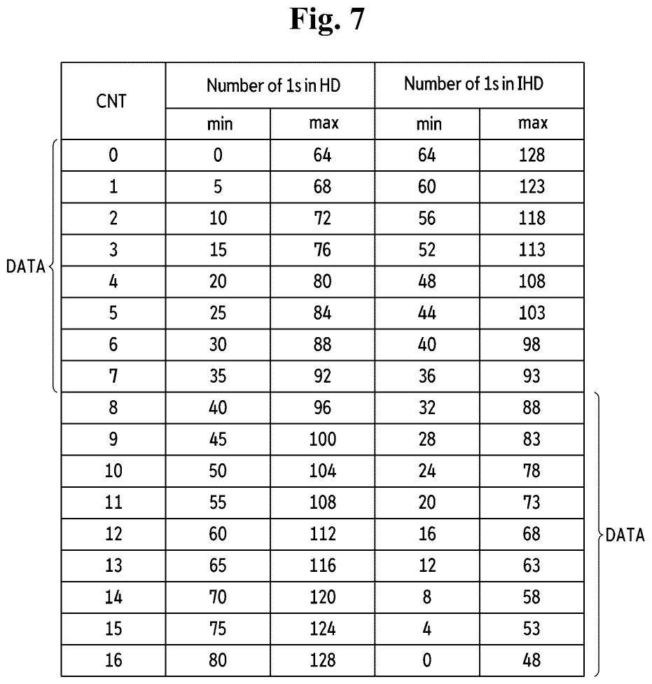

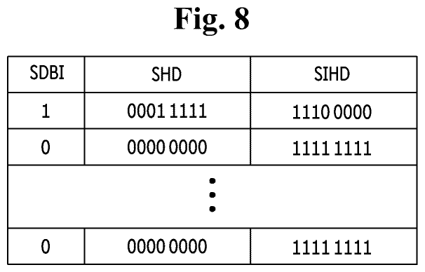

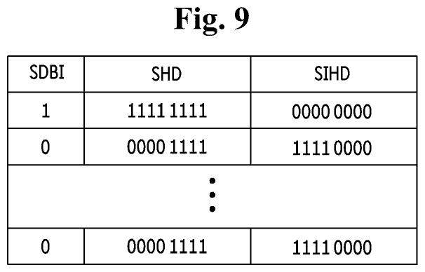

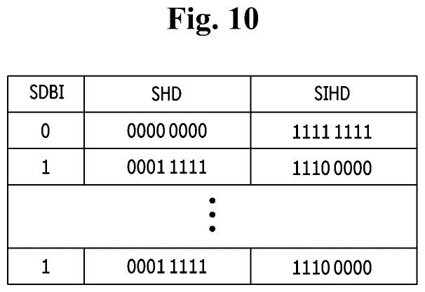

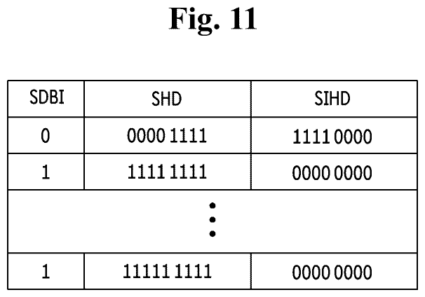

FIG. 5 is a block diagram illustrating a data transformation circuit according to some embodiments. FIG. 6 is a diagram illustrating the data transformation circuit according to some embodiments. FIGS. 7 through 11 are tables provided to explain the operation and effects of the data transformation circuit of FIG. 3.

Referring to FIGS. 4 through 6, the data transformation circuit 400 may include a DBI decoder 410, a DBI counter 420, an inverter 430, an indicator generation circuit 440, and a data selection circuit 450.

The DBI decoder 410 may receive the input data DQ and the DBI signal DBI. In some embodiments, the input data DQ may include a plurality of first through sixteenth sub-input data SDQ1 through SDQ16. The DBI signal DBI may also include a plurality of first through sixteenth sub-DBI signals SDBI1 through SDBI16. For example, if the input data DQ is a 128-bit signal, each of the first through sixteenth sub-input data (e.g., each of SDQ1 through SDQ16) may be 8-bit signals. Additionally, for each of the 8-bit sub-input data SDQ1 through SDQ16, the respective 1-bit sub-DBI signals SDBI1 through SDBI16 may be provided.

The DBI decoder 410 may restore the host data HD based on the input data DQ and the DBI signal DBI. Specifically, the DBI decoder 410 may sequentially restore first through sixteenth sub-host data SHD1 through SHD16 from the first through sixteenth sub-input data SDQ1 through SDQ16, respectively, and the first through sixteenth sub-DBI signals SDBI1 through SDBI16, respectively, and may repeat this operation to restore the host data. For example, when the first sub-DBI signal SDBI1, which is 0, is provided to the DBI decoder 410, the first sub-input data SDQ1 and the first sub-host data SHD1 may be identical. For example, if the first sub-input data SDQ1 is 00000001 and the first sub-DBI signal SDBI1 is 0, the first sub-host data SHD1 may also be 00000001.

Meanwhile, when the second sub-DBI signal SDBI2, which is 1, is provided, the second sub-host data SHD2 may be the inverted form of the second sub-input data SDQ2. For example, if the second sub-input data SDQ2 provided to the DBI decoder 410 is 11100000 and the second sub-DBI signal SDBI2 is 1, the second sub-host data SHD2 may be 00011111, which is the inverted form of the second sub-input data SDQ2.

It is to be noted that a binary bit may be referred to have a first, second, third, or fourth value in the present disclosure. Each of the first, second, third, or fourth value may be either 0 or 1. Therefore, despite using the terms “first” through “fourth,” in some examples, at least two of the first to fourth values may be the same.

The inverter 430 may receive the restored host data HD from the DBI decoder 410. In some embodiments, the inverter 430 may generate inverted host data IHD by inverting all the bits of the host data HD. Specifically, the inverter 430 may sequentially invert the first through sixteenth sub-host data SHD1 through SHD16 and repeat this operation to generate the inverted host data IHD. For example, if the first sub-host data SHD1 provided to the inverter 430 is 00000001, the first sub-inverted host data SIHD1 may be 11111110. Similarly, if the second sub-host data SHD2 provided to the inverter 430 is 00011111, the second sub-inverted host data SIHD2 may be 11100000.

The data selection circuit 450 may receive the inverted host data IHD and the host data HD from the inverter 430 and the DBI decoder 410. In some embodiments, the data selection circuit 450 may output either the host data HD or the inverted host data IHD as the write data DATA to be stored in the memory cell array 200, based on the indicator signal I that will be described later. By maintaining the number of 1s in the write data DATA below a predetermined level, power consumption can be reduced, thereby ensuring the stability of the memory system 1. The process of generating the write data DATA and the indicator signal I through the DBI counter 420 and the indicator generation circuit 440 will be described later in detail.

The DBI counter 420 may receive the DBI signal DBI. In some embodiments, the DBI counter 420 may count the number of 1s in the DBI signal DBI and generate a counting value CNT. For example, if the DBI signal DBI is a 16-bit signal, it may be 0100000000000000. In this case, the DBI counter 420 may generate a counting value CNT of 1. Conversely, if the DBI signal DBI is 1011111111111111, the DBI counter 420 may generate a counting value CNT of 15.

The indicator generation circuit 440 may receive the counting value CNT from the DBI counter 420. In some embodiments, the indicator generation circuit 440 may generate the indicator signal I based on the counting value CNT. Specifically, the indicator generation circuit 440 may generate an indicator signal I of either 1 or 0 based on whether the counting value CNT exceeds a reference value. The indicator signal I may be a 1-bit signal.

Referring to FIGS. 6 and 7, for example, if the input data DQ is 128 bits, the DBI signal DBI may be 16 bits. The counting value CNT, which is the number of 1s in the 16-bit DBI signal DBI, may range from 0 to 16.

For example, if the counting value CNT is 1, the minimum number of 1s in the host data HD may be 5, and the maximum number of 1s in the host data HD may be 68. Additionally, the minimum number of 1s in the inverted host data IHD may be 60, and the maximum number of 1s in the inverted host data IHD may be 123.

Specifically, referring to FIGS. 4, 7, and 8, if the counting value CNT is 1, the first sub-DBI signal SDBI1 may be 1, and the second through sixteenth sub-DBI signals SDBI2 through SDBI16 may each be 0.

For example, the DBI signal DBI may be 1000000000000000. If the first sub-DBI signal SDBI1 is 1, the minimum number of 1s included in the first sub-host data SHD1 may be 5. If the second through sixteenth sub-DBI signals SDBI2 through SDBI16 are all 0, the minimum numbers of 1s included in the second through sixteenth sub-host data SHD2 through SHD16 may each be 0. In this case, the minimum number of 1s included in the host data HD may be 5.

Conversely, if the DBI signal DBI is 1000000000000000, the maximum number of 1s included in the inverted host data IHD may be 123. In other words, if the host data HD has the minimum number of 1s, the inverted host data IHD, which is the fully inverted form of the host data HD, may have the maximum number of 1s.

Referring to FIGS. 4, 7, and 9, for example, the DBI signal DBI may be 1000000000000000. If the first sub DBI signal SDBI1 is 1, the maximum number of 1s included in the first sub-host data SHD1 may be 8. If the second through sixteenth sub-DBI signals SDBI2 through SDBI16 are all 0, the maximum numbers of 1s included in the second through sixteenth sub-host data SHD2 through SHD16 may each be 4. In this case, the maximum number of 1s included in the host data HD may be 68.

Conversely, if the DBI signal DBI is 1000000000000000, the minimum number of 1s included in the inverted host data IHD may be 60. In other words, if the host data HD has the maximum number of 1s, the inverted host data IHD, which is the fully inverted form of the host data HD, may have the minimum number of 1s.

Additionally, for example, if the counting value CNT is 15, the minimum number of 1s in the host data HD may be 75, and the maximum number may be 124. Similarly, the minimum number of 1s in the inverted host data IHD may be 4, and the maximum number may be 53.

Specifically, referring to FIGS. 4, 7, and 10, when the counting value CNT is 15, the first sub-DBI signal SDBI1 may be 0, and the second through sixteenth sub-DBI signals SDBI2 through SDBI16 may each be 1.

For example, the DBI signal DBI may be 0111111111111111. If the first sub-DBI signal SDBI1 is 0, the minimum number of 1s included in the first sub-host data SHD1 may be 0. If the second through sixteenth sub-DBI signals SDBI2 through SDBI16 are all 1, the minimum numbers of 1s included in the second through sixteenth sub-host data SHD2 through SHD16 may each be 5. In this case, the minimum number of 1s included in the host data HD may be 75.

Conversely, if the DBI signal DBI is 0111111111111111, the maximum number of 1s included in the inverted host data IHD may be 53. In other words, if the host data HD has the minimum number of 1s, the fully inverted host data IHD may have the maximum number of 1s.

Referring to FIGS. 4, 7, and 11, for example, the DBI signal DBI may be 0111111111111111. If the first sub-DBI signal SDBI1 is 0, the maximum number of 1s included in the first sub-host data SHD1 may be 4. If the second through sixteenth sub-DBI signals SDBI2 through SDBI16 are all 1, the maximum numbers of 1s included in the second through sixteenth sub-host data SHD2 through SHD16 may each be 8. In this case, the maximum number of 1s included in the host data HD may be 124.

Conversely, if the DBI signal DBI is 0111111111111111, the minimum number of 1s included in the inverted host data IHD may be 4. In other words, if the host data HD has the maximum number of 1s, the fully inverted host data IHD may have the minimum number of 1s.

Referring again to FIG. 7, when the counting value CNT is 1, the maximum number of 1s that may be included in the host data HD may be 68, and the maximum number of 1s that may be included in the inverted host data IHD may be 123. In this case, it may be advantageous to select the host data HD as the write data DATA to be stored in the memory cell array 200 in order to maintain the number of 1s in the write data DATA below a predetermined level.

Conversely, when the counting value CNT is 15, the maximum number of 1s that may be included in the host data HD may be 124, and the maximum number of 1s that may be included in the inverted host data IHD may be 53. In this case, it may be advantageous to select the inverted host data IHD as the write data DATA to be stored in the memory cell array 200 in order to maintain the number of 1s in the write data DATA below a predetermined level.

Similarly, when the counting value CNT ranges from 0 to 16, if the counting value CNT does not exceed 7, it may be advantageous to select the host data HD as the write data DATA to be stored in the memory cell array 200. If the counting value CNT exceeds 7, it may be advantageous to select the inverted host data IHD as the write data DATA to be stored in the memory cell array 200.

Accordingly, for example, the indicator generation circuit 440 may generate an indicator signal I of 0 when the counting value CNT does not exceed a reference value of 7. Conversely, if the counting value CNT exceeds the reference value of 7, the indicator generation circuit 440 may generate an indicator signal I of 1. Alternatively, the indicator generation circuit 440 may generate an indicator signal I of 1 when the counting value CNT does not exceed the reference value of 7, and generate an indicator signal I of 0 when the counting value CNT exceeds the reference value of 7.

Referring again to FIG. 5, the data selection circuit 450 may receive the inverted host data IHD and the host data HD from the inverter 430 and the DBI decoder 410, and may receive the indicator signal I from the indicator generation circuit 440.

In some embodiments, in response to an indicator signal I of 0, the data selection circuit 450 may select the host data HD and output it as the write data DATA. Alternatively, in response to an indicator signal I of 1, the data selection circuit 450 may select the inverted host data IHD and output it as the write data DATA. Conversely, the data selection circuit 450 may select the host data HD as the write data DATA in response to an indicator signal I of 1, and may select the inverted host data IHD as the write data DATA in response to an indicator signal I of 0.

The write data DATA and the indicator signal I output by the data transformation circuit 400 may be stored in the memory cell array 200 of FIG. 3.

By maintaining the total number of 1s included in the write data DATA stored in the memory cell array 200 below a predetermined level through the data transformation circuit 400, power consumption can be reduced, thereby ensuring the stability of the memory system 1.

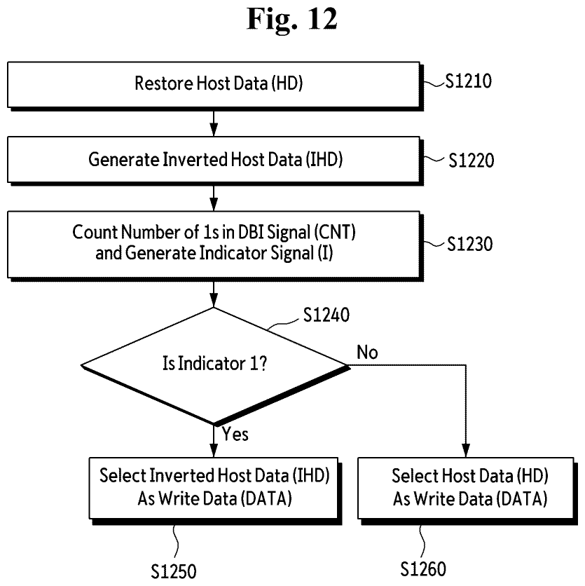

FIG. 12 is a flowchart illustrating the operation of the data transformation circuit of FIG. 5.

Referring to FIGS. 5 and 12, the data transformation circuit 400 may receive the input data DQ and the DBI signal DBI and may restore the host data HD (S1210).

The DBI decoder 410 may receive the input data DQ and the DBI signal DBI, generate the host data HD, and provide the host data HD to the inverter 430 and the data selection circuit 450.

The data transformation circuit 400 may generate the inverted host data IHD based on the host data HD (S1220).

The inverter 430 may receive the host data HD, generate the inverted host data IHD, and provide the inverted host data IHD to the data selection circuit 450.

The data transformation circuit 400 may generate the counting value CNT by counting the number of 1s included in the DBI signal DBI, and may generate the indicator signal I based on the counting value CNT (S1230).

The DBI counter 420 may receive the DBI signal DBI and may generate the counting value CNT by counting the number of 1s included in the DBI signal DBI. The DBI counter 420 may provide the counting value CNT to the indicator generation circuit 440.

The indicator generation circuit 440 may generate the indicator signal I based on the counting value CNT and provide the indicator signal I to the data selection circuit and the memory cell array 200.

The data transformation circuit 400 may determine whether the indicator signal I is 1 (S1240). If the indicator signal I corresponds to 1, the data transformation circuit 400 may select the inverted host data IHD as the write data DATA. If the indicator signal I corresponds to 0, the data transformation circuit 400 may select the host data HD as the write data DATA.

The data selection circuit 450 may receive the host data HD, the inverted host data IHD, and the indicator signal I, generate the write data DATA, and provide the write data DATA to the memory cell array 200.

By maintaining the number of 1s included in the write data DATA below a predetermined level, power consumption can be reduced, thereby ensuring the stability of the memory system 1.

The restoration of the host data HD is illustrated as occurring before counting the number of 1s in the DBI signal DBI, but alternatively, the restoration of the host data HD and the counting of the number of 1s in the DBI signal DBI may be performed simultaneously or in reverse order.

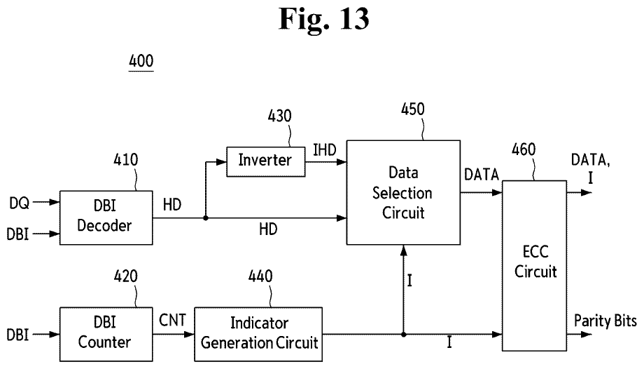

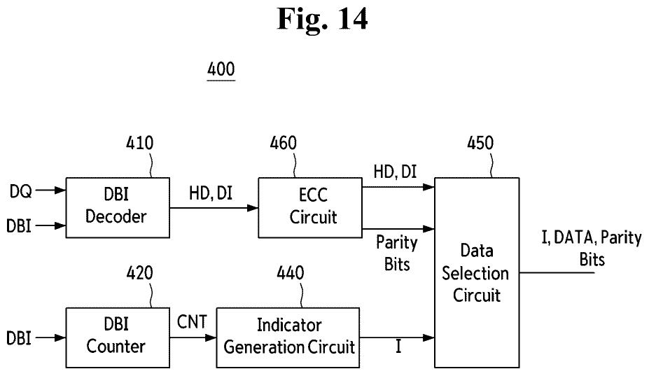

FIGS. 13 and 14 are block diagrams illustrating data transformation circuits according to some embodiments. The embodiment of FIG. 13 is similar to the embodiment of FIG. 5, and thus will hereinafter be described, focusing mainly on the differences from the embodiment of FIG. 5.

Referring to FIG. 13, write data DATA and an indicator signal I output by a data selection circuit 450 and an indicator generation circuit 440 may be provided to an error correction code (ECC) circuit 460.

The ECC circuit 460 may be configured to correct errors in the write data DATA and the indicator signal I to be stored in the memory cell array 200. For example, the ECC circuit 460 may perform ECC encoding on the write data DATA and the indicator signal I, thereby generating parity bits. The generated parity bits may be stored in the memory cell array 200 along with the write data DATA and the indicator signal I. Thereafter, the ECC circuit 460 may perform ECC decoding based on the write data DATA, the indicator signal I, and the parity bits read from the memory cell array 200, thereby correcting errors in the read write data DATA and indicator signal I.

Referring to FIG. 14, a data transformation circuit 400 may include a DBI decoder 410, a DBI counter 420, an indicator generation circuit 440, a data selection circuit 450, and an ECC circuit 460.

The DBI decoder 410 may receive input data DQ and a DBI signal DBI. The DBI decoder 410 may restore host data HD based on the input data DQ and the DBI signal DBI. Additionally, while the DBI counter 420 and the indicator generation circuit 440 are operating, the DBI decoder 410 may provide the host data HD and a default indicator signal DI to the ECC circuit 460 to prioritize generating parity bits for the host data HD and an indicator signal I. For example, the default indicator signal DI may be a signal with a value of 0. That is, the default indicator signal DI may be a signal for selecting the host data HD as write data DATA.

The ECC circuit 460 may be configured to correct errors in the host data HD and the default indicator signal DI. For example, the ECC circuit 460 may perform ECC encoding on the host data HD and the default indicator signal DI, thereby generating parity bits. The host data HD, the default indicator signal DI, and the parity bits may be provided to the data selection circuit 450.

Meanwhile, the DBI counter 420 may receive the DBI signal DBI. In some embodiments, the DBI counter 420 may count the number of 1s in the DBI signal DBI and generate a counting value CNT. For example, if the DBI signal DBI is a 16-bit signal, it may be 0100000000000000, and the DBI counter 420 may generate a counting value CNT of 1. Conversely, if the DBI signal DBI is 1011111111111111, the DBI counter 420 may generate a counting value CNT of 15.

The indicator generation circuit 440 may receive the counting value CNT from the DBI counter 420. In some embodiments, the indicator generation circuit 440 may generate the indicator signal I based on the counting value CNT. Specifically, the indicator generation circuit 440 may generate an indicator signal I of 1 or 0 based on whether the counting value CNT exceeds a reference value. For example, if the counting value CNT exceeds the reference value, an indicator signal I of 1 may be generated. Alternatively, if the counting value CNT does not exceed the reference value, an indicator signal I of 0 may be generated. The indicator signal I may be a 1-bit signal.

The data selection circuit 450 may receive the host data HD, the default indicator signal DI, and the indicator signal I from the ECC circuit 460 and the indicator generation circuit 440.

In some embodiments, the data selection circuit 450 may output either the host data HD or the inverted host data IHD as the write data DATA to be stored in the memory cell array 200 based on the indicator signal I.

For example, in response to the indicator signal I being identical to the default indicator signal DI, the data selection circuit 450 may output the host data HD as is as the write data DATA. Alternatively, in response to the indicator signal I being different from the default indicator signal DI, the data selection circuit 450 may output inverted host data IHD, in which all bits of the host data HD are inverted, as the write data DATA.

In some implementations, when the host data is selected as the write data DATA, the write data DATA, the indicator signal I, and the parity bits output by the data selection circuit 450 may be stored in the memory cell array 200 of FIG. 3. The parity bits are corresponding to the host data.

In some implementations, when the inverted host data is selected as the write data DATA, the data selection circuit 450 is configured to output the write data DATA, the indicator signal I, and updated parity bits to the memory cell array 200 of FIG. 3. The updated parity bits are corresponding to the inverted host data. In some other implementations, the updated parity bits are generated by the data selection circuit 450, e.g., by updating the parity bits based on at least the inverted host data.

It is to be noted that although an inverter (e.g., the inverter 430 of FIG. 13) is not depicted in FIG. 14, the example implementations shown in FIG. 14 can include an inverter 430 configured to invert all bits of the host data and output the inverted host data to the data selection circuit 450.

By maintaining the total number of 1s included in the write data DATA stored in the memory cell array 200 below a predetermined level through the data transformation circuit 400, power consumption can be reduced, thereby ensuring the stability of the memory system 1.

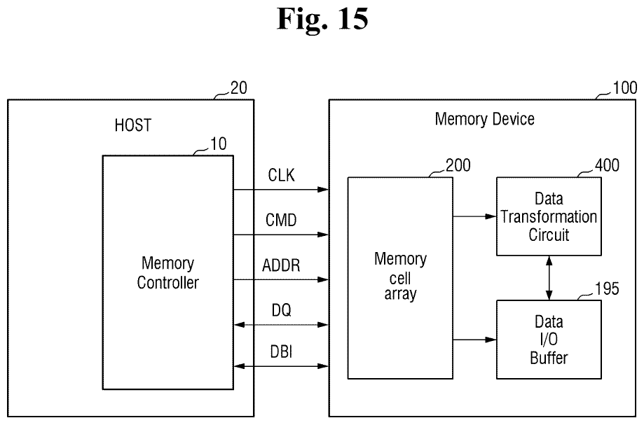

FIG. 15 is a block diagram illustrating a memory system according to some embodiments.

Referring to FIG. 15, a host device 20 may include a memory controller 10. In other words, unlike the memory system 1 of FIG. 1, in which the memory controller 10 is located outside the host device 20, the host device 20 of FIG. 15 may include the memory controller 10. The host device 20 may control a memory device 100 via the memory controller 10. Here, the host device 20 may communicate with the memory device 100 based on one of the standards such as Double Data Rate (DDR), Low Power Double Data Rate (LPDDR), Graphics Double Data Rate (GDDR), Wide I/O, High Bandwidth Memory (HBM), Hybrid Memory Cube (HMC), or Compute Express Link (CXL).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a decoder configured to
receive first input data that is based on host data and a first data bus inversion (DBI) signal indicating whether the first input data is inverted, and
output the host data;
a counter configured to count a number of bits with a first value in the first DBI signal;
an indicator generation circuit configured to generate an indicator signal based on a first counting value indicative of the number of bits with the first value in the first DBI signal; and
a data selection circuit configured to receive the host data and, in response to the indicator signal, select write data to be stored in a memory cell array.

2. The memory device of claim 1, wherein
the first input data includes first sub-input data and second sub-input data,
the first DBI signal includes a first sub-DBI signal having one bit and indicating whether the first sub-input data is inverted, and a second sub-DBI signal having one bit and indicating whether the second sub-input data is inverted, and
the decoder is configured to:
in response to the one bit of the first sub-DBI signal having a second value, generate first sub-host data by inverting all bits of the first sub-input data;
in response to the one bit of the first sub-DBI signal having a third value different from the second value, generate first sub-host data that is identical to the first sub-input data;
in response to the one bit of the second sub-DBI signal having the second value, generate second sub-host data by inverting all bits of the second sub-input data;
in response to the one bit of the second sub-DBI signal having the third value, generate second sub-host data that is identical to the second sub-input data; and
output the host data including the first sub-host data and the second sub-host data.

3. The memory device of claim 2, further comprising:
an inverter configured to receive the host data and provide, to the data selection circuit, inverted host data, wherein the inverted host data is an inverted form of all bits of the host data.

4. The memory device of claim 1, wherein
the first input data includes first sub-input data and second sub-input data,
the first DBI signal includes a first sub-DBI signal having one bit and indicating whether the first sub-input data is inverted, and a second sub-DBI signal having one bit and indicating whether the second sub-input data is inverted, and
the counter is configured to provide the first counting value to the indicator generation circuit.

5. The memory device of claim 4, wherein the indicator generation circuit is configured to:
in response to the first counting value exceeding a first reference value, generate an indicator signal having a second value; and
in response to the first counting value being equal to or less than the first reference value, generate an indicator signal having a third value different from the second value.

6. The memory device of claim 5, wherein the data selection circuit is configured to:
in response to the indicator signal having the second value, select inverted host data as the write data, wherein the inverted host data is an inverted form of all bits of the host data; and
in response to the indicator signal having the third value, select the host data as the write data.

7. The memory device of claim 6, wherein
the first counting value exceeds the first reference value, and
a maximum number of bits with a fourth value in the host data is smaller than a maximum number of bits with the fourth value in the inverted host data.

8. The memory device of claim 6, wherein
the first counting value is equal to or less than the first reference value, and
a maximum number of bits with a fourth value in the host data is greater than a maximum number of bits with the fourth value in the inverted host data.

9. The memory device of claim 5, wherein the indicator signal has one bit.

10. The memory device of claim 1, further comprising:
an inverter configured to receive the host data and provide, to the data selection circuit, inverted host data, wherein the inverted host data is an inverted form of the bits of the host data; and
an error correction code (ECC) circuit configured to receive the write data, the indicator signal and output parity bits.

11. The memory device of claim 10, wherein
the decoder is configured to provide the host data to the inverter and the data selection circuit;
the inverter is configured to provide the inverted host data to the data selection circuit;
the data selection circuit is configured to provide the write data to the ECC circuit;
the counter is configured to provide the first counting value to the indicator generation circuit;
the indicator generation circuit is configured to provide the indicator signal to the data selection circuit and the ECC circuit; and
the ECC circuit is configured to provide the write data, the indicator signal, and the parity bits to the memory cell array.

12. The memory device of claim 1, further comprising:
an ECC circuit configured to receive the host data and a default indicator signal and output parity bits,
wherein
the decoder is configured to provide the host data and the default indicator signal having a second value to the ECC circuit,
the ECC circuit is configured to provide the host data, the default indicator signal, and the parity bits to the data selection circuit,
the counter is configured to provide the first counting value to the indicator generation circuit,
the indicator generation circuit is configured to provide the indicator signal to the data selection circuit,
in response to the indicator signal having a third value different from the second value of the default indicator signal, the data selection circuit is configured to (i) provide inverted host data as the write data to the memory cell array, wherein the inverted host data is an inverted form of all bits of the host data; (ii) provide the indicator signal to the memory cell array; and (iii) provide updated parity bits based on the write data to the memory cell array, and
in response to the indicator signal having the second value, the data selection circuit is configured to (i) provide the host data as the write data to the memory cell array; (ii) provide the indicator signal to the memory cell array; and (iii) provide the parity bits to the memory cell array.

13. An operating method of a memory device, comprising:
generating, by a decoder, host data based on first input data and a first data bus inversion (DBI) signal, the first DBI signal indicating whether the first input data is inverted;
generating, by a counter, a first counting value based on a number of bits with a first value in the first DBI signal;
generating, by an indicator generation circuit, an indicator signal having one bit based on the first counting value;
generating, by an inverter, inverted host data by inverting all bits of the host data; and
selecting and outputting, by a data selection circuit, the host data or the inverted host data as write data based on the indicator signal.

14. The operating method of claim 13, wherein
the first input data includes first sub-input data and second sub-input data,
the first DBI signal includes a first sub-DBI signal having one bit and indicating whether the first sub-input data is inverted, and a second sub-DBI signal having one bit and indicating whether the second sub-input data is inverted, and
generating, by the decoder, the host data comprises: in response to the first sub-DBI signal having a second value, generating first sub-host data by inverting all bits of the first sub-input data; in response to the first sub-DBI signal having a third value different from the second value, generating first sub-host data that is identical to the first sub-input data; in response to the second sub-DBI signal having the second value, generating second sub-host data by inverting all bits of the second sub-input data; in response to the second sub-DBI signal having the third value, generating second sub-host data that is identical to the second sub-input data; and outputting the host data including the first sub-host data and the second sub-host data.

15. The operating method of claim 14, wherein generating, by the indicator generation circuit, the indicator signal comprises:
in response to the first counting value exceeding a first reference value, generating the indicator signal having the second value, and
wherein selecting, by the data selection circuit, the host data or the inverted host data based on the indicator signal comprises: in response to the indicator signal having the second value, selecting the inverted host data.

16. The operating method of claim 14, wherein generating, by the indicator generation circuit, the indicator signal comprises:
in response to the first counting value being equal to or less than a first reference value, generating the indicator signal having the third value different from the second value, and
wherein selecting, by the data selection circuit, the host data or the inverted host data based on the indicator signal comprises: in response to the indicator signal having the third value, selecting the host data.

17. The operating method of claim 15, wherein
the first counting value exceeds the first reference value, and
a maximum number of bits with a fourth value in the host data is smaller than a maximum number of bits with the fourth value in the inverted host data.

18. The operating method of claim 15, wherein
the first counting value is equal to or less than the first reference value, and
a maximum number of bits with a fourth value in the host data is greater than a maximum number of bits with the fourth value in the inverted host data.

19. The operating method of claim 13, further comprising:
generating, by an error correction code (ECC) circuit, parity bits based on the write data and the indicator signal.

20. A memory device comprising:
a decoder configured to
receive first input data that is based on host data and a first data bus inversion (DBI) signal indicating whether the first input data is inverted, and
output the host data;
an inverter configured to generate inverted host data by inverting all bits of the host data;
a counter configured to count a number of bits with a first value in the first DBI signal;
an indicator generation circuit configured to generate an indicator signal based on a first counting value indicative of the number of bits with the first value in the first DBI signal;
an error correction code (ECC) circuit configured to receive the host data and a default indicator signal and output parity bits;
a data selection circuit configured to receive the host data and the inverted host data, in response to the indicator signal, select the host data or the inverted host data as write data; and
a memory cell array configured to store (i) the write data; (ii) the indicator signal; and (iii) the parity bits or updated parity bits.
